(19) United States
(12) Patent Application Publication
(10) Pub. No.: US 2025/0133883 A1
(43) Pub. Date: Apr. 24, 2025

(54) DISPLAY DEVICE

(71) Applicant: LG Display Co., Ltd., Seoul (KR)

(72) Inventors: You-Yong JIN, Seoul (KR); Keongjin LEE, Seoul (KR)

(73) Assignee: LG Display Co., Ltd., Seoul (KR)

(21) Appl. No.: 18/793,595

(22) Filed: Aug. 2, 2024

(30) Foreign Application Priority Data
Oct. 24, 2023 (KR) 10-2023-0143306

(51) Int. Cl. H01L 33/58; B60K 35/22; H01L 25/16; H01L 33/10; H01L 33/40; H01L 33/42; H01L 33/62

(52) U.S. Cl. CPC H10H 20/855; B60K 35/22; H01L 25/167; H10H 20/814; H10H 20/833; H10H 20/835; H10H 20/857

(57) ABSTRACT

A display device in one example can include a substrate on which a plurality of pixels are disposed, where each pixel includes a plurality of subpixels configured to display different colors. The display device further includes a first light-emitting element and a second light-emitting element disposed in each of the plurality of subpixels, a first lens disposed to overlap a light-emitting area of the first light-emitting element and configured to provide a viewing angle of a first value, and a plurality of second lenses disposed to overlap the light-emitting areas of the second light-emitting elements and configured to provide a viewing angle of a second value lower than the viewing angle of the first value. Each of the first light-emitting element and the second light-emitting element includes an anode.

### CROSS-REFERENCE TO RELATED APPLICATIONS

This application claims priority to Korean Patent Application No. 10-2023-0143306 filed on Oct. 24, 2023, in the Korean Intellectual Property Office, the entire contents of which is hereby expressly incorporated by reference into the present application.

### BACKGROUND

### Field

The present disclosure relates to a display device, and more particularly, to a display device capable of controlling a viewing angle.

### Discussion of the Related Art

With the advancement of technologies in the modern society, display devices are being used in various ways to provide information to users. The display devices can be included in electronic display boards, which simply transfer visual information in one direction. The display devices can also included in various high-technology electronic devices that identify user inputs and provide information in response to the identified inputs.

For example, the display device can be included in a vehicle and provide various information to a driver and a fellow passenger in the vehicle. However, the display device in the vehicle is needed to appropriately display content so as not to hinder the operation of the vehicle. For example, the display device needs to restrict a display of content that can decrease the driver's concentration on driving and safety while the vehicle travels.

### SUMMARY OF THE DISCLOSURE

An object to be achieved by various embodiments of the present disclosure is to provide a display device capable of selectively controlling a viewing angle.

Another object to be achieved by various embodiments of the present disclosure is to provide a display device capable of suppressing a high-angle leak of light.

Still another object to be achieved by various embodiments of the present disclosure is to provide a display device capable of improving reliability related to a function of selectively providing different viewing angle modes.

Yet another object to be achieved by various embodiments of the present disclosure is to provide a display device capable of minimizing the occurrence of a severe safety problem which can be caused when content, which need not be shared, is shared with a driver of a vehicle.

Still yet another object to be achieved by various embodiments of the present disclosure is to provide a low-reflection, low-power display device capable of minimizing light reflected by a lower electrode that overlaps an area between a plurality of lenses disposed above one light-emitting element.

Objects of the present disclosure are not limited to the above-mentioned objects, and other objects, which are not mentioned above, can be clearly understood by those skilled in the art from the following descriptions.

In one aspect of the present disclosure, there is provided a display device including a substrate on which a plurality of pixels each including a plurality of subpixels configured to display different colors is disposed; a first light-emitting element and a second light-emitting element disposed in each of the plurality of subpixels; a first lens disposed to overlap a light-emitting area of the first light-emitting element and configured to provide a viewing angle of a first value; and a plurality of second lenses disposed to overlap light-emitting areas of the second light-emitting elements and configured to provide a viewing angle of a second value lower than the viewing angle of the first value, in which the first light-emitting element and the second light-emitting element each include: an anode including a reflective layer, and in which an opening portion is disposed in the reflective layer and overlaps an area between the plurality of second lenses.

In another aspect of the present disclosure, there is provided a display device including a substrate including a display area in which a plurality of subpixels is disposed, and a non-display area disposed along a periphery of the display area; a first light-emitting element and a second light-emitting element disposed in each of the plurality of subpixels and each comprising an anode, a light-emitting layer disposed on the anode, and a cathode disposed on the light-emitting layer, and the anode comprises a reflective layer; a first lens disposed to overlap a light-emitting area of the first light-emitting element and configured to provide a viewing angle of a first value; and a plurality of second lenses disposed to overlap light-emitting areas of the second light-emitting elements and configured to provide a viewing angle of a second value lower than the viewing angle of the first value, in which the reflective layer of the second light-emitting element has an opening portion disposed in an area that overlaps an area between the plurality of second lenses.

Other detailed matters of the example embodiments of the present disclosure are included in the detailed description and the drawings.

The display device according to one or more aspects of the present disclosure can selectively control the viewing angle.

The display device according to one or more aspects of the present disclosure can suppress a high-angle leak of light by minimizing light reflected by the lower electrode.

The display device according to one or more aspects of the present disclosure can improve the reliability of the display device by minimizing distortion of a viewing angle range set to provide a plurality of lenses.

The display device according to one or more aspects of the present disclosure can minimize the user safety problem by suppressing a situation in which the content, which need not be shared, is shared with the driver of the vehicle.

According to one or more aspects of the present disclosure, it is possible to provide a low-reflection display device in which an opening portion is disposed in the lower electrode, and the light reflected by the lower electrode is minimized.

The effects according to one or more aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an exemplified view illustrating a display device according to an embodiment of the present disclosure;

FIG. 2 is a functional block diagram of the display device according to the embodiment of the present disclosure;

FIG. 3 is a circuit diagram illustrating an example of a pixel circuit of the display device according to the embodiment of the present disclosure;

FIG. 4 is an enlarged top plan view illustrating an arrangement of lenses included in one pixel of the display device according to the embodiment of the present disclosure;

FIG. 5 is a cross-sectional view taken along line A-A′ in FIG. 4;

FIG. 6 is a cross-sectional view taken along line B-B′ in FIG. 4;

FIG. 7A is an enlarged top plan view of a display device according to another embodiment of the present disclosure;

FIG. 7B is a cross-sectional view taken along line C-

C′ in FIG. 7A; and

FIG. 8 is an enlarged top plan view of a display device according to still another embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular can include plural unless expressly stated otherwise.

Components are interpreted to include an ordinary error range even if not expressly stated.

When the position relation between two parts is described using the terms such as ‘on’, ‘above’, ‘below’, ‘next’, one or more parts can be positioned between the two parts unless the terms are used with the term ‘immediately’ or ‘directly’.

When an element or layer is disposed “on” another element or layer,, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Further, the term “can” encompasses all the meanings and coverages of the term “may.” The term “disclosure” is interchangeably used with, or encompasses all the meanings and coverages of, the term “invention.”

All the components of each display device or apparatus according to all embodiments of the present disclosure are operatively coupled and configured.

Hereinafter, various embodiments of the present disclosure will be described in detail with reference to accompanying drawings.

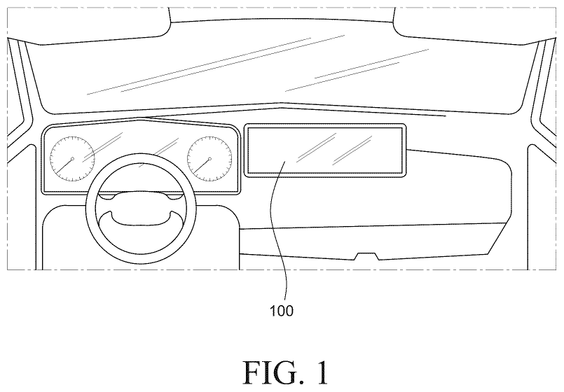

FIG. 1 is an exemplified view illustrating a display device according to an embodiment of the present disclosure.

With reference to FIG. 1, a display device 100 can be disposed on at least a part of a dashboard of a vehicle. The dashboard of the vehicle includes a configuration disposed at a front side of a front seat (e.g., a driver seat or a passenger seat) of the vehicle. For example, the dashboard of the vehicle can be equipped with an input configuration for manipulating various functions (e.g., an air conditioner, an audio system, and a navigation system) in the vehicle.

In the embodiment, the display device 100 can be disposed on the dashboard of the vehicle and operate as an input part for manipulating at least some of various functions of the vehicle. The display device 100 can provide various types of information related to the vehicle, e.g., driving information of the vehicle (e.g., a current speed of the vehicle, a remaining fuel amount, and a traveling distance), and information on components of the vehicle (e.g., a degree of damage to a vehicle tire).

In the embodiment, the display device 100 can be disposed to traverse the driver seat and the passenger seat disposed as the front seat of the vehicle. Users of the display device 100 can include a driver of the vehicle, and a fellow passenger seated in the passenger seat. Both the driver and the fellow passenger in the vehicle can use the display device 100.

In the embodiment, a part of the display device 100 can be illustrated in FIG. 1. The display device 100 can be illustrated as a display panel among various components included in the display device 100. Specifically, for example, the display device can be illustrated as at least a part of a display area and at least a part of a non-display area of the display panel. The components, which exclude the components illustrated in FIG. 1 among the components of the display device 100, can be mounted in the vehicle (or at least a part of the vehicle).

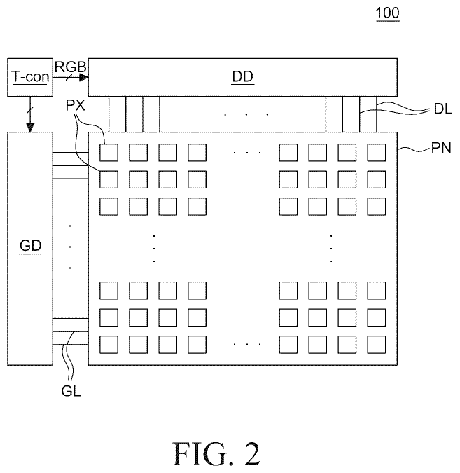

FIG. 2 is a functional block diagram of the display device according to the embodiment of the present disclosure.

An electroluminescent display device can be applied as the display device according to the embodiment of the present disclosure. The electroluminescent display is a self-luminous display and can be manufactured to be light and thin since it does not require a separate light source, unlike the liquid crystal display having a separate light source. In addition, the electroluminescent display has advantages in terms of power consumption due to a low voltage driving, and is excellent in terms of a color implementation, a response speed, a viewing angle, and a contrast ratio (CR). For example, an organic light-emitting diode display device, a quantum-dot light-emitting diode display device, or an inorganic light-emitting diode display device can be used as the electroluminescent display device.

With reference to FIG. 2, the display device 100 can include a display panel PN, a data drive circuit DD, a gate drive circuit GD, and a timing controller T-con, but components of the display device of the present disclosure are not limited thereto. Meanwhile, all the components of each display device according to all embodiments of the present disclosure are operatively coupled and configured.

In the embodiment, the display panel PN can create an image to be provided to the user. For example, the display panel PN can create and display images, which are to be provided to the user, through a plurality of pixels PX in which pixel circuits are disposed.

The data drive circuit DD, the gate drive circuit GD, and the timing controller T-con can provide signals for operating the pixels PX through signal lines. For example, the signal lines can include data lines DL and gate lines GL.

In some instances, the display device can further include a power source unit. In this case, the signal for operating the pixel PX can be provided through a power line that connects the power source unit and the display panel PN. According to the embodiment, the power source unit can provide power to the data drive circuit DD and the gate drive circuit GD. The data drive circuit DD and the gate drive circuit GD can operate on the basis of power provided from the power source unit.

For example, the data drive circuit DD can apply data signals to the pixels PX through the data lines DL, the gate drive circuit GD can apply gate signals to the pixels PX through the gate lines GL, and the power source unit can supply power voltages to the pixels PX through power voltage supply lines.

The timing controller T-con can control the data drive circuit DD and the gate drive circuit GD. For example, the timing controller T-con can realign digital video data, which are inputted from the outside, to fit the resolution of the display panel PN and supply the video data to the data drive circuit DD. The timing controller T-con may generate the gate control signal and the data control signal based on timing signals synchronized with the input image signal, such as a dot clock signal, a data enable signal, and horizontal/vertical synchronization signals. Here, the horizontal synchronization signal is a signal representing a time taken to display one horizontal line of a screen and the vertical synchronization signal is a signal representing a time taken to display a screen of one frame. The data enable signal may correspond to a signal indicating a period for which a data voltage is supplied to the pixel. The timing controller T-con may control operation timings of the gate drive circuit GD and the data driver by supplying the gate control signal to the gate drive circuit GD and supplying the data control signal to the data drive circuit DD.

The data drive circuit DD can convert digital video data, which are inputted from the timing controller T-con, into analog data voltages in response to the data control signal and supply the analog data voltages to the plurality of data lines. The data drive circuit DD may be configured with at least one data IC. In this case, as an example, the data IC of the data drive circuit DD may be connected to non-display area on a corresponding one side of the display panel, or may be mounted directly on the non-display area. As an example, the data IC of the data drive circuit DD may be mounted on a flexible circuit film and connected to the non-display area on a corresponding one side of the display panel.

The gate drive circuit GD can generate a scan signal and a light-emitting signal (or light emission control signal) in response to the gate control signal. The gate drive circuit GD can include a scan drive part and a light-emitting signal drive part. The scan drive part can generate scan signals in a row-sequential manner to operate at least one scan line connected to each pixel row and supply the scan signals to the scan lines. The light-emitting signal drive part can generate light-emitting signals in a row-sequential manner to operate at least one light-emitting signal line connected to each pixel row and supply the light-emitting signals to the light-emitting signal lines.

According to the embodiment, the gate drive circuit GD can be disposed on the display panel PN in a gate-driver-in-panel (GIP) manner. For example, the gate drive circuit GD can be divided into a plurality of gate drivers and respectively disposed on at least two side surfaces of the display panel PN, but the number of the gate drive circuit GD and the placement thereof are not limited thereto. For example, one gate drive circuit GD may be disposed at one side of the display panel.

The display panel PN can include a display area and a non-display area. The non-display area is configured to be in the vicinity of the display area, partially or fully surround the display area.

The display area can include the plurality of pixels PX. In the pixel PX, the plurality of data lines (e.g., the data lines DL in FIG. 2) and the plurality of gate lines (e.g., the gate lines GL in FIG. 2) intersect, and subpixels can be disposed in each intersection area. The subpixels included in one pixel PX can emit light with different colors. For example, the pixel PX can implement blue, red, and green by using three subpixels. However, the present disclosure is not limited thereto. In some instances, the pixel PX can further include a subpixel for further implementing a particular color (e.g., white).

For example, the plurality of sub pixels may include red, green, and blue sub-pixels, in which the red, green, and blue sub-pixels may be disposed in a repeated manner. Alternatively, the plurality of sub pixels may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the sub-pixels are not limiting, and may be configured in various forms according to light-emitting characteristics, device lifespans, and device specifications.

Meanwhile, the sub-pixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

In the pixel PX, the area for implementing blue can be referred to as a blue subpixel, an area for implementing red can be referred to as a red subpixel, and an area for implementing green can be referred to as a green subpixel.

In the embodiment, the pixel PX can include a plurality of subpixels. The plurality of subpixels can each be divided into first and second lens areas that provide different viewing angles. For example, one pixel PX can include a first lens area configured to define a first viewing angle by providing light within a first range, and a second lens area configured to define a second viewing angle by providing light within a second range. The first range can correspond to a range larger than the second range.

The non-display area can be disposed along a periphery of the display area. Various constituent elements for operating the pixel circuit disposed in the pixel PX can be disposed in the non-display area. For example, at least a part of the gate drive circuit GD can be disposed in the non-display area. The non-display area can be referred to as a bezel area.

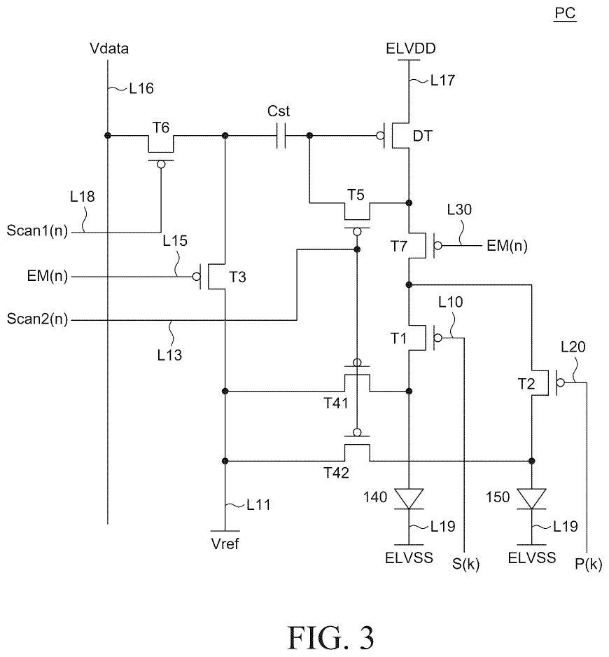

FIG. 3 is a circuit diagram illustrating an example of the pixel circuit of the display device according to the embodiment of the present disclosure. The pixel PX can include the plurality of subpixels for implementing different colors, and pixel circuits PC respectively corresponding to the plurality of subpixels. FIG. 3 illustrates an example of the pixel circuit PC of one subpixel disposed in the pixel PX.

The pixel circuits PC may include at least one thin-film transistor (TFT) and at least one capacitor. However, the present disclosure is not limited thereto. For example, a number of thin-film transistors TFTs in the pixel circuit of the present disclosure may be two or more, and a number of capacitor may be one or more, for example, the pixel circuit of the present disclosure may be a 3T2C pixel circuit including three TFTs and two capacitors, a 5T1C pixel circuit including five TFTs and one capacitor, a 5T2C pixel circuit including five TFTs and two capacitors, a 7T2C pixel circuit including seven TFTs and two capacitors, or the like.

Active layers of thin-film transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

With reference to FIG. 3, the pixel circuit PC can include nine transistors and one capacitor.

The pixel circuit PC can include a first transistor T1, a second transistor T2, a third transistor T3, a fourth-first transistor T41, a fourth-second transistor T42, a fifth transistor T5, a sixth transistor T6, a seventh transistor T7, a driving transistor DT, and a capacitor Cst.

At least some of the nine transistors included in the pixel circuit PC can be an n-type transistor or a p-type transistor. In the case of the p-type transistor, a low-level voltage of each of the driving signals can mean a voltage that turns on the TFT, and a high-level voltage of each of the driving signals can mean a voltage that turns off the TFTs. In the case of the N-type transistor, a high-level voltage of each of the driving signals may mean a voltage that turns on the TFT, and a low-level voltage of each of the driving signals may mean a voltage that turns off the TFTs.

In this case of the p-type transistor, the low-level voltage can correspond to a predesignated voltage lower than the high-level voltage. For example, the low-level voltage can include a voltage corresponding to a range of −8 V to −12 V. The high-level voltage can correspond to a predesignated voltage higher than the low-level voltage. For example, the high-level voltage can include a voltage corresponding to a range of 12 V to 16 V. According to the embodiment, the low-level voltage can be referred to as a first voltage, and the high-level voltage can be referred to as a second voltage. In this case, the first voltage can have a lower value than the second voltage. However, the range of the low-level voltage and the range of the high-level voltage are provided for illustrative purposes only. However, the present disclosure is not limited thereto.

The first or second electrode of the transistor, which will be described below, can mean the source or drain electrode. However, the terms ‘first electrode’ and ‘second electrode’ are just terms for distinguishing the electrodes. What corresponds to the electrode is not limited. In addition, for each electrode, the first electrode may not refer to the same electrode. For example, a first electrode of the first transistor T1 can mean a source electrode of the first transistor T1, and a first electrode of the sixth transistor T6 can mean a drain electrode of the sixth transistor T6.

In the embodiment, the driving transistor DT can be connected to the first transistor T1, which is connected to a first light-emitting element 140, and the second transistor T2 connected to a second light-emitting element 150. For example, a second electrode of the driving transistor DT can be connected to the first transistor T1 and the second transistor T2.

In the embodiment, the driving transistor DT can be connected to a first power line L17 configured to provide a high-potential power voltage ELVDD. For example, the first electrode of the driving transistor DT can be connected to the first power line L17. In case that the driving transistor DT is turned on, the high-potential power voltage ELVDD, which is supplied through the first power line L17, can be transmitted from the first electrode to the second electrode of the driving transistor DT.

In the embodiment, the first transistor T1 can be connected to at least one of the first light-emitting element 140, the second transistor T2, the fourth-first transistor T41, and the seventh transistor T7.

For example, the first electrode of the first transistor T1 can be connected to at least one of the second transistor T2 and the seventh transistor T7. Further, the seventh transistor T7 can be connected to the driving transistor DT and the fifth transistor T5. A second electrode of the first transistor T1 can be connected to at least one of the first light-emitting element 140 and the fourth-first transistor T41. A gate electrode of the first transistor T1 can be connected to a first control line L10. The first transistor T1 can be turned on or off by a first control signal S(k) provided through the first control line L10. In case that the first transistor T1 is turned on, a voltage can be inputted to the first light-emitting element 140 (e.g., an anode electrode of the first light-emitting element 140) through the driving transistor DT and the seventh transistor T7.

In this case, the first control signal S(k) can include a k-th first control signal supplied to a k-th column on the basis that the pixel circuit PC is disposed in the k-th column (k is a positive integer). The first control signal S(k) can be provided by the mode controller (or mode control circuit) and control an operation (or light emission) of the first light-emitting element 140 on which a first lens is disposed.

In the embodiment, the second transistor T2 can be connected to at least one of the second light-emitting element 150, the first transistor T2, the fourth-second transistor T42, and the seventh transistor T7.

For example, a first electrode of the second transistor T2 can be connected to at least one of the first transistor T1 and the seventh transistor T7. A second electrode of the second transistor T2 can be connected to at least one of the fourth-second transistor T42 and the second light-emitting element 150. Further, the seventh transistor T7 can be connected to the driving transistor DT and the fifth transistor T5. A gate electrode of the second transistor T2 can be connected to a second control line L20. The second transistor T2 can be turned on or off by a second control signal P(k) provided through the second control line L20. In case that the second transistor T2 is turned on, a voltage can be inputted to the second light-emitting element 150 (e.g., an anode electrode of the second light-emitting element 150) through the driving transistor DT and the seventh transistor T7.

In this case, the second control signal P(k) can include a k-th second control signal supplied to the k-th column on the basis that the pixel circuit PC is disposed in the k-th column (k is a positive integer). The second control signal P(k) can be provided by the mode controller (or mode control circuit) and control an operation (or light emission) of the second light-emitting element 150 on which a second lens is disposed.

In the embodiment, the first lens can be disposed on the first light-emitting element 140. A viewing angle of an area in which the first light-emitting element 140 is disposed can correspond to a first value by the first lens. For example, the viewing angle of the area in which the first light-emitting element 140 is disposed can be equal to the first value or more than the first value. The second lens can be disposed on the second light-emitting element 150. A viewing angle of an area in which the second light-emitting element 150 is disposed can correspond to a second value by the second lens. The second value can be smaller than the first value. For example, the viewing angle of the area in which the second light-emitting element 150 is disposed can be equal to the second value or less than the second value.

In the embodiment, the area of the pixel circuit PC, in which the first light-emitting element 140 is disposed, can have the viewing angle of the first value that allows light to be provided to a range corresponding to the passenger seat and a driver seat adjacent to the passenger seat. The area, in which the second light-emitting element 150 is disposed, can have the viewing angle of the second value that allows light to be provided to a range corresponding to the passenger seat.

In the embodiment, the third transistor T3 can be connected to at least one of the fourth-first transistor T41, the fourth-second transistor T42, the sixth transistor T6, and the capacitor Cst.

For example, a first electrode of the third transistor T3 can be connected to the sixth transistor T6 and the capacitor Cst. A second electrode of the third transistor T3 can be connected to the fourth-first transistor T41 and the fourth-second transistor T42. A gate electrode of the third transistor T3 can be connected to a light-emitting signal line L15 configured to supply a light-emitting signal EM(n). The light-emitting signal EM(n) can correspond to an n-th light-emitting signal EM(n) supplied to an n-th row on the basis that the pixel circuit PC is disposed in the n-th pixel row (n is a positive integer). The third transistor T3 can be turned on or off by the light-emitting signal EM(n). The second electrode of the third transistor T3 can be connected to a reference voltage line L11, e.g., a second power line configured to supply a reference voltage Vref.

In the embodiment, the fourth-first transistor T41 can be connected to at least one of the first transistor T1, the third transistor T3, and the first light-emitting element 140.

For example, a first electrode of the fourth-first transistor T41 can be connected to the third transistor T3. A second electrode of the fourth-first transistor T41 can be connected to the first transistor T1 and the first light-emitting element 140. A gate electrode of the fourth-first transistor T41 can be connected to an n-th second scan line L13. Therefore, the fourth-first transistor T41 can be supplied with an n-th second scan signal Scan2(n) and turned on or off by the n-th second scan signal Scan2(n).

In the embodiment, the fourth-second transistor T42 can be connected to at least one of the second transistor T2, the third transistor T3, and the second light-emitting element 150.

For example, a first electrode of the fourth-second transistor T42 can be connected to the third transistor T3. A second electrode of the fourth-second transistor T42 can be connected to the second transistor T2 and the second light-emitting element 150. A gate electrode of the fourth-second transistor T42 can be connected to the n-th second scan line L13. Therefore, the fourth-second transistor T42 can be supplied with the n-th second scan signal Scan2(n) and turned on or off by the n-th second scan signal Scan2(n).

In the embodiment, the fifth transistor T5 can be connected to at least one of the driving transistor DT, the fourth-first transistor T41, the fourth-second transistor T42, the capacitor Cst, and the seventh transistor T7.

For example, a first electrode of the fifth transistor T5 can be connected to the driving transistor DT and the capacitor Cst. A second electrode of the fifth transistor T5 can be connected to the driving transistor DT and the seventh transistor T7. A gate electrode of the fifth transistor T5 can be connected to the n-th second scan line L13 configured to supply a second scan signal Scan2(n) in the n-th row. The fifth transistor T5 can be supplied with the n-th second scan signal Scan2(n) and turned on or off by the n-th second scan signal Scan2(n).

According to the embodiment, an n-th first scan line L18 can provide an n-th first scan signal. In this case, the n-th first scan signal can be provided to a gate electrode of the sixth transistor T6. The n-th second scan line L13 can provide an n-th second scan signal. In this case, the n-th second scan signal can be provided to the gate electrode of each of the fourth-first transistor T41, the fourth-second transistor T42, and the fifth transistor T5.

In the embodiment, the sixth transistor T6 can be connected to at least one of the third transistor T3 and the capacitor Cst.

For example, a first electrode of the sixth transistor T6 can be connected to the third transistor T3 and the capacitor Cst. A second electrode of the sixth transistor T6 can be connected to a data line L16 configured to supply a data voltage Vdata. A gate electrode of the sixth transistor T6 can be connected to the n-th first scan line L18 configured to supply an n-th first scan signal Scan1(n). The sixth transistor T6 can be supplied with the n-th first scan signal Scan1(n) and turned on or off by the n-th first scan signal Scan1(n). In case that the sixth transistor T6 is turned on, the data voltage Vdata can be transmitted from the second electrode to the first electrode.

In the embodiment, the seventh transistor T7 can be connected to at least one of the first transistor T1, the second transistor T2, the fifth transistor T5, and the driving transistor DT.

For example, a first electrode of the seventh transistor T7 can be connected to at least one of the fifth transistor T5 and the driving transistor DT. A second electrode of the seventh transistor T7 can be connected to at least one of the first transistor T1 and the second transistor T2. A gate electrode of the seventh transistor T7 can be connected to a light-emitting signal line L30 configured to provide the light-emitting signal EM(n). The seventh transistor T7 can be turned on or off on the basis of the light-emitting signal EM(n). In case that the seventh transistor T7 is turned on, a voltage (or electric current) can be provided from the first electrode to the second electrode of the seventh transistor T7.

In the embodiment, the first light-emitting element 140 and/or the second light-emitting element 150 can be connected to a third power line L19 that supplies a low-potential power voltage ELVSS. For example, a cathode electrode of the first light-emitting element 140 and a cathode electrode of the second light-emitting element 150 can be connected to the third power line L19 and supplied with the low-potential power voltage ELVSS.

According to the embodiment, the low-potential power voltage can be a ground voltage (e.g., 0 V (volt)). For example, the cathode electrode of the first light-emitting element 140 and the cathode electrode of the second light-emitting element 150 can be supplied with a voltage corresponding to the ground. However, the present disclosure is not limited thereto.

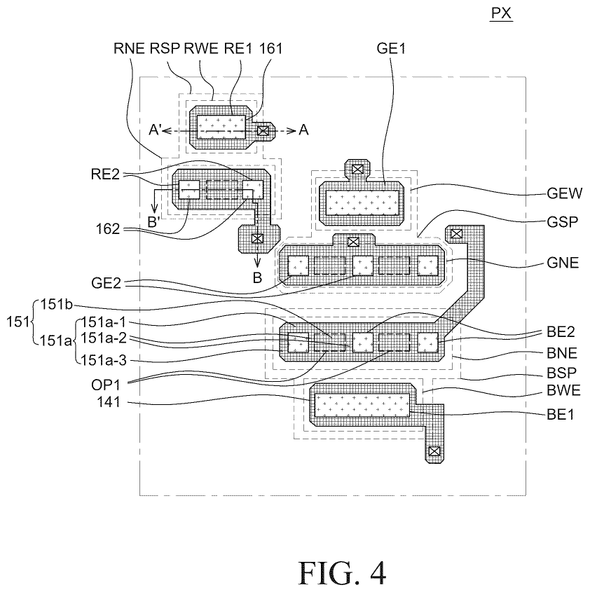

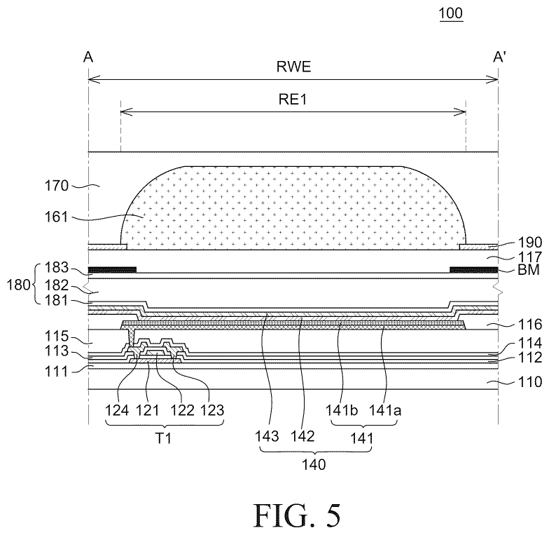

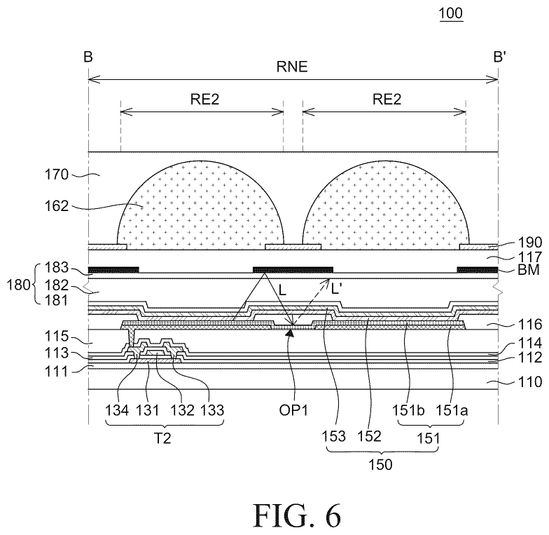

FIG. 4 is an enlarged top plan view illustrating an arrangement of lenses included in one pixel of the display device according to the embodiment of the present disclosure. FIG. 5 is a cross-sectional view taken along line A-A′ in FIG. 4. FIG. 6 is a cross-sectional view taken along line B-B′ in FIG. 4.

Particularly, FIG. 4 illustrates a planar surface of the pixel PX in case that three subpixels RSP, GSP, and BSP are disposed in one pixel PX. FIG. 5 illustrates a cross-section taken along line A-A′ in FIG. 4, and FIG. 6 illustrates a cross-section taken along line B-B′ in FIG. 4. However, for convenience of description, FIGS. 5 and 6 illustrate only areas corresponding to a first lens area RWE and a second lens area RNE of a red subpixel RSP among the plurality of subpixels RSP, GSP, and BSP. However, the other subpixels GSP and BSP can also have the same or similar configuration.

First, with reference to FIG. 4, the pixel PX can include the plurality of subpixels RSP, GSP, and BSP that displays different colors. For example, the pixel PX can include the blue subpixel BSP configured to implement blue, the red subpixel RSP configured to implement red, and the green subpixel GSP configured to implement green. According to the embodiment, the blue subpixel BSP can correspond to a first subpixel, the red subpixel RSP can correspond to a second subpixel, and the green subpixel GSP can correspond to a third subpixel. The pixel circuits PC can respectively correspond to the subpixels RSP, GSP, and BSP. The pixel circuit PC (e.g., the pixel circuit PC in FIG. 3) can be disposed to correspond to each of the subpixels RSP, GSP, and BSP.

The subpixels RSP, GSP, and BSP can each include first lens areas RWE, GWE, and BWE and second lens areas RNE, GNE, and BNE that provide different viewing angles.

The second lens areas RNE, GNE, and BNE in the subpixels RSP, GSP, and BSP can operate independently of the first lens areas RWE, GWE, and BWE in the corresponding pixel PX. For example, the subpixels RSP, GSP, and BSP can each include the first light-emitting elements 140 (e.g., the first light-emitting elements 140 in FIG. 3) positioned in the first lens areas RWE, GWE, and BWE in the corresponding subpixels RSP, GSP, and BSP, and the second light-emitting elements 150 (e.g., the second light-emitting elements 150 in FIG. 3) positioned in the second lens areas RNE, GNE, and BNE in the corresponding subpixels RSP, GSP, and BSP.

In one pixel PX, the first light-emitting element 140 and the second light-emitting element 150 can be disposed in each of the first lens areas RWE, GWE, and BWE and the second lens areas RNE, GNE, and BNE in the plurality of subpixels RSP, GSP, and BSP.

For example, one pixel PX can include the first light-emitting element 140 disposed in the first lens area RWE in the red subpixel RSP, the second light-emitting element 150 disposed in the second lens area RNE in the red subpixel RSP, the first light-emitting element 140 disposed in the first lens area GWE in the green subpixel GSP, the second light-emitting element 150 disposed in the second lens area GNE in the green subpixel GSP, the first light-emitting element 140 disposed in the first lens area BWE in the blue subpixel BSP, and the second light-emitting element 150 disposed in the second lens area BNE in the blue subpixel BSP.

With reference to FIG. 4, a plurality of first lenses 161, which is disposed to overlap a light-emitting area EA1 of the first light-emitting element 140, is disposed in the first lens areas RWE, GWE, and BWE in the subpixels RSP, GSP, and BSP. Second lenses 162, which are disposed to overlap a light-emitting area EA2 of the second light-emitting element 150, are disposed in the second lens areas RNE, GNE, and BNE in the subpixels RSP, GSP, and BSP. In this case, the first lens areas RWE, GWE, and BWE can each have the viewing angle of the first value, and the second lens areas RNE, GNE, and BNE can each have the viewing angle of the second value higher than the viewing angle of the first value. Meanwhile, the specific arrangement structure of the plurality of first lenses 161 and the second lens 162 will be described below with reference to FIGS. 5 and 6.

With reference to FIGS. 5 and 6 together, the display device 100 according to the embodiment of the present disclosure can include a substrate 110, a buffer layer 111, a gate insulation layer 112, an interlayer insulation layer 113, a lower protective layer 114, an overcoating layer 115, the first transistor T1, the second transistor T2, the first light-emitting element 140, the second light-emitting element 150, an encapsulation member 180, a touch insulation layer 117, a touch sensor part 190, a first lens 161, the second lens 162, and a lens protective layer 170.

The substrate 110 can be disposed to support the other constituent elements disposed on the substrate 110. The substrate 110 can include an insulating material. The substrate 110 can include a transparent material. For example, the substrate 110 can include glass or plastic. In some exemplary embodiments, the substrate 110 can be made of a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS). However, the present disclosure is not limited thereto.

The buffer layer 111 can be positioned between the substrate 110 and a drive part of each of the subpixels RSP, GSP, and BSP. The buffer layer 111 can suppress contamination caused by the substrate 110 during a process of forming the drive part. For example, a top surface of the substrate 110, which is directed toward the drive part of each of the subpixels RSP, GSP, and BSP, can be covered by the buffer layer 111. The drive part of each of the subpixels RSP, GSP, and BSP can be positioned on the buffer layer 111.

The buffer layer 111 can include an insulating material. For example, the buffer layer 111 can include an inorganic insulating material such as silicon oxide (SiOx) and silicon nitride (SiNx). The buffer layer 111 can have a multilayer structure. For example, the buffer layer 111 can have a stacked structure including a film made of silicon nitride (SiNx) and a film made of silicon oxide (SiOx). For example, the buffer layer 111 can be configured as a single layer or multilayer made of at least one of silicon nitride (SiNx) and silicon oxide (SiOx). For example, the buffer layer 111 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. However, the buffer layer 111 may be excluded in accordance with the structure or properties of the display device. However, the present disclosure is not limited thereto.

The gate insulation layer 112 can be positioned on the buffer layer 111. The gate insulation layer 112 can extend between the semiconductor layer and the gate electrode of the transistor. For example, gate electrodes 122 and 132 of the first and second transistors T1 and T2 can be insulated from semiconductor layers 121 and 131 of the first and second transistors T1 and T2 by the gate insulation layer 112. The gate insulation layer 112 can cover the first semiconductor layer 121 and the second semiconductor layer 131 in each of the subpixels RSP, GSP, and BSP. The gate electrodes 122 and 132 of the first and second transistors T1 and T2 can be positioned on the gate insulation layer 112.

The gate insulation layer 112 can include an insulating material. The gate insulation layer 112 may have a single layer or multilayer structure. For example, the gate insulation layer 112 can include an inorganic insulating material such as silicon oxide (SiOx) and silicon nitride (SiNx). For example, the gate insulation layer 112 may be configured as a single layer or multilayer made of at least one of silicon nitride (SiNx) and silicon oxide (SiOx). For example, the gate insulation layer 112 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. The gate insulation layer 112 can include a material having high For example, the gate insulation layer 112 can permittivity. include a high-K material such as hafnium oxide (HfO). However, the present disclosure is not limited thereto.

The interlayer insulation layer 113 can be positioned on the gate insulation layer 112. The interlayer insulation layer 113 can extend between the gate electrode and the source electrode and between the gate electrode and the drain electrode of the transistor. For example, source electrodes 123 and 133 and drain electrodes 124 and 134 of the first and second transistors T1 and T2 can be insulated from the gate electrodes 122 and 132 by the interlayer insulation layer 113, respectively. The interlayer insulation layer 113 can cover the gate electrodes 122 and 132 of the first and second transistors T1 and T2. The source electrodes 123 and 133 and the drain electrodes 124 and 134 in each of the subpixels RSP, GSP, and BSP can be positioned on the interlayer insulation layer 113. The gate insulation layer 112 and the interlayer insulation layer 113 can expose source and drain areas of the semiconductor layers 121 and 131.

The interlayer insulation layer 113 can include an insulating material. For example, the interlayer insulation layer 113 can include an inorganic insulating material such as silicon oxide (SiOx) and silicon nitride (SiNx). For example, the interlayer insulation layer 113 may be configured as a single layer or multilayer made of at least one of silicon nitride (SiNx) and silicon oxide (SiOx). For example, the interlayer insulation layer 113 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. The interlayer insulation layer 113 can be positioned on the gate insulation layer 112. However, the present disclosure is not limited thereto.

The lower protective layer 114 can be positioned on the interlayer insulation layer 113. The lower protective layer 114 can suppress damage to the drive part caused by external moisture and impact. The lower protective layer 114 can extend along surfaces of the first and second transistors T1 and T2. The lower protective layer 114 can be in contact with the interlayer insulation layer 113 outside the drive part positioned in each of the subpixels RSP, GSP, and BSP.

The lower protective layer 114 can include an insulating material. For example, the lower protective layer 114 can include an inorganic insulating material such as silicon oxide (SiOx) and silicon nitride (SiNx). For example, the lower protective layer 114 may be configured as a single layer or multilayer made of at least one of silicon nitride (SiNx) and silicon oxide (SiOx). For example, the lower protective layer 114 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si). However, the present disclosure is not limited thereto.

The overcoating layer 115 can be positioned on the lower protective layer 114. The overcoating layer 115 can remove a level difference caused by the drive part in each of the subpixels RSP, GSP, and BSP. For example, a top surface of the overcoating layer 115, which is opposite to the substrate 110, can be a flat surface. However, the present disclosure is not limited thereto.

The overcoating layer 115 can include an insulating material. The overcoating layer 115 can include a material different from the material of the lower protective layer 114. For example, the overcoating layer 115 can include an organic insulating material. For example, the overcoating layer 115 may include an organic insulating material such as benzocyclobutene (BCB)-based resin, acrylic resin, or polyimide. However, the present disclosure is not limited thereto.

The first transistor T1 can include the first semiconductor layer 121, the first gate electrode 122, the first source electrode 123, and the first drain electrode 124.

For example, the first semiconductor layer 121 can be positioned between the buffer layer 111 and the gate insulation layer 112, and the first gate electrode 122 can be positioned between the gate insulation layer 112 and the interlayer insulation layer 113. The first source electrode 123 and the first drain electrode 124 can be positioned between the interlayer insulation layer 113 and the lower protective layer 114. The first gate electrode 122 can overlap a channel area of the first semiconductor layer 121. The first source electrode 123 can be electrically connected to the source area of the first semiconductor layer 121. The first drain electrode 124 can be electrically connected to the drain area of the first semiconductor layer 121.

The second transistor T2 can include the second semiconductor layer 131, the second gate electrode 132, the second source electrode 133, and the second drain electrode 134.

For example, the second semiconductor layer 131 can be positioned on the same layer as the first semiconductor layer 121, the second gate electrode 132 can be positioned on the same layer as the first gate electrode 122, and the second source electrode 133 and the second drain electrode 134 can be positioned on the same layer as the first source electrode 123 and the first drain electrode 124. However, the present disclosure is not limited thereto, the second semiconductor layer 131 may be positioned on a different layer from the first semiconductor layer 121, the second gate electrode 132 may be positioned on a different layer from the first gate electrode 122, and the second source electrode 133 and the second drain electrode 134 may be positioned on a different layer from the first source electrode 123 and the first drain electrode 124.

The first transistor T1 can be formed simultaneously with the second transistor T2. However, the present disclosure is not limited thereto.

The first light-emitting element 140 and the second light-emitting element 150 in each of the subpixels RSP, GSP, and BSP can be positioned on the overcoating layer 115 in each of the corresponding subpixels RSP, GSP, and BSP. For example, the first lower electrode 141 of the first light-emitting element 140 can be electrically connected to the first drain electrode 124 (or the first source electrode 123) of the first transistor T1 through contact holes formed through the lower protective layer 114 and the overcoating layer 115, and the second lower electrode 151 of the second light-emitting element 150 can be electrically connected to the second drain electrode 134 (or the second source electrode 133) of the second transistor T2 through contact holes formed through the lower protective layer 114 and the overcoating layer 115.

The first light-emitting element 140 can emit light with a particular color. For example, the first light-emitting element 140 can include a first lower electrode 141, a first light-emitting layer 142, and a first upper electrode 143 sequentially stacked on the substrate 110. In this case, the first lower electrode 141 can be an anode electrode of the first light-emitting element 140, and the first upper electrode 143 can be a cathode electrode of the first light-emitting element 140.

The first lower electrode 141 includes a reflective layer 141a, and a transparent conductive layer 141b disposed on the reflective layer 141a. The first lower electrode 141 can have a multilayer structure including the reflective layer 141a and the transparent conductive layer 141b.

Meanwhile, FIG. 5 illustrates that the first lower electrode 141 including the reflective layer 141a and the transparent conductive layer 141b disposed on the reflective layer 141a. However, the first lower electrode 141 can have a structure in which a reflective layer is positioned between a plurality of transparent conductive layers. However, the present disclosure is not limited thereto.

The reflective layer 141a is disposed on the overcoating layer 115. The reflective layer 141a can include a material having high reflectance. For example, the first lower electrode 141 can include metal such as aluminum (Al) and silver (Ag). However, the present disclosure is not limited thereto.

The transparent conductive layer 141b is disposed on the reflective layer 141a. For example, the transparent conductive layer 141b can be made of a transparent conductive material such as indium tin oxide (ITO) and indium zinc oxide (IZO). However, the present disclosure is not limited thereto.

The first light-emitting layer 142 can create light with brightness corresponding to a voltage difference between the first lower electrode 141 and the first upper electrode 143. For example, the first light-emitting layer 142 can include an emission material layer (EML) including a light-emitting material. The light-emitting material can include an organic material, an inorganic material, or a hybrid material.

The first light-emitting layer 142 can have a multilayer structure. For example, the first light-emitting layer 142 can further include at least one of a hole injection layer (HIL), a hole transport layer (HTL), an electron transport layer (ETL), and an electron injection layer (EIL).

The first upper electrode 143 can include an electrically conductive material. The first upper electrode 143 can include a material different from the material of the first lower electrode 141. A transmittance rate of the first upper electrode 143 can be higher than a transmittance rate of the first lower electrode 141. For example, the first upper electrode 143 can be configured as a transparent electrode made of a transparent conductive material such as ITO and IZO. Alternatively, the first upper electrode 143 can be a transparent electrode made of a metallic material with a very small thickness. Therefore, in the display device 100 according to the embodiment of the present disclosure, the light created by the first light-emitting layer 142 can be discharged through the first upper electrode 143.

In case that the display device according to the exemplary embodiment of the present disclosure is a top emission type display device, the first lower electrode 141 may further include a reflective layer made of a metallic material, for example, a material such as aluminum (Al) or silver (Ag) excellent in reflection efficiency so that light emitted from the light-emitting layer EML is reflected by the first lower electrode 141 and propagates upward direction, i.e., toward the first upper electrode 143. On the contrary, in case that the display device is a bottom emission type display device, the first lower electrode 141 may be made of only a transparent electrically conductive material.

The second light-emitting element 150 can implement the same color as the first light-emitting element 140 disposed in the same subpixels RSP, GSP, and BSP. For example, the second light-emitting element 150 can include a second lower electrode 151, a second light-emitting layer 152, and a second upper electrode 153 sequentially stacked on the substrate 110. In this case, the second lower electrode 151 can be an anode electrode of the second light-emitting element 150, and the second upper electrode 153 can be a cathode electrode of the second light-emitting element 150.

The second lower electrode 151 includes a reflective layer 151a disposed on the overcoating layer 115, and a transparent conductive layer 151b disposed on the reflective layer 151a. The second lower electrode 151 can have a multilayer structure including the reflective layer 151a and the transparent conductive layer 151b.

Meanwhile, FIG. 6 illustrates that the second lower electrode 151 including the reflective layer 151a and the transparent conductive layer 151b disposed on the reflective layer 151a. However, the second lower electrode 151 can have a structure in which a reflective layer is positioned between a plurality of transparent conductive layers. However, the present disclosure is not limited thereto.

In case that the display device according to the exemplary embodiment of the present disclosure is a top emission type display device, the second lower electrode 151 may further include a reflective layer made of a metallic material, for example, a material such as aluminum (Al) or silver (Ag) excellent in reflection efficiency so that light emitted from the light-emitting layer EML is reflected by the second lower electrode 151 and propagates upward direction, i.e., toward the second upper electrode 153. On the contrary, in case that the display device is a bottom emission type display device, the second lower electrode 151 may be made of only a transparent electrically conductive material.

With reference to FIGS. 4 and 6, an opening portion OP1 is disposed in the reflective layer 151a of the second lower electrode 151 and overlaps an area between the plurality of second lenses 162. With reference to FIG. 4, the reflective layer 151a of the second lower electrode 151 includes a first part 151a-1, a plurality of second parts 151a-2, and a third part 151a-3. Further, the opening portion OP1 has a hole shape surrounded by the first part 151a-1, the plurality of second parts 151a-2, and the third part 151a-3 of the reflective layer 151a.

With reference to FIG. 4, the first part 151a-1 of the reflective layer 151a of the second lower electrode 151 can include one portion connected to the plurality of second parts 151a-2, and the other portion extending outward from one portion and connected to the second transistor T2. Therefore, the first part 151a-1 can be connected to the second transistor T2. For example, the first part 151a-1 can be connected to the second transistor T2 through a contact hole formed in the overcoating layer 115 in an area corresponding to the other portion extending outward from one portion of the reflective layer 151a. However, the present disclosure is not limited thereto.

The plurality of second parts 151a-2 of the reflective layer 151a of the second lower electrode 151 extends from the first part 151a-1 and is disposed to overlap the plurality of second lenses 162. The plurality of second parts 151a-2 can be parts corresponding to an area of the reflective layer 151a of the second lower electrode 151 in which the plurality of second lenses 162 is disposed.

The third part 151a-3 of the reflective layer 151a of the second lower electrode 151 can be a part of the reflective layer 151a that is disposed opposite to the first part 151a-1 based on the plurality of second parts 151a-2. The third part 151a-3 can be disposed opposite to the first part 151a-1 and connected to the plurality of second parts 151a-2. For example, the first part 151a-1 and the third part 151a-3 of the reflective layer 151a of the second lower electrode 151 may extend in a first direction, the plurality of second parts 151a-2 may extend in a second direction perpendicular to the first direction, and the first part 151a-1 and the third part 151a-3 are connected to each other through the plurality of second parts 151a-2, so as to form a plurality of closed shape. However, the present disclosure is not limited thereto.

The reflective layer 151a can include a material having high reflectance. For example, the second lower electrode 151 can include metal such as aluminum (Al) and silver (Ag). However, the present disclosure is not limited thereto.

The transparent conductive layer 151b is disposed on the reflective layer 151a. For example, the transparent conductive layer 151b can be made of a transparent conductive material such as indium tin oxide (ITO) and indium zinc oxide (IZO). However, the present disclosure is not limited thereto.

With reference to FIG. 6, the transparent conductive layer 151b is also disposed in the opening portion OP1 of the reflective layer 151a. Therefore, the transparent conductive layer 151b can be disposed on the overcoating layer 115 through the opening portion OP1 of the reflective layer 151a.

With reference to FIGS. 5 and 6, the second light-emitting layer 152 can correspond to the first light-emitting layer 142, and the second upper electrode 153 can correspond to the first upper electrode 143. For example, the second light-emitting layer 152 and the second upper electrode 153 of the second light-emitting element 150 can be formed to have the same structures as the first light-emitting layer 142 and the first upper electrode 143 of the first light-emitting element 140. For example, the light-emitting layers 142 and 152 and the upper electrodes 143 and 153 of the first and second light-emitting elements 140 and 150 can be formed to have the same structure. However, the present disclosure is not limited thereto. In some instances, at least some configurations of the light-emitting layers 142 and 152 and the upper electrodes 143 and 153 of the first and second light-emitting elements 140 and 150 can be formed to be different from one another.

In the embodiment, the second light-emitting layer 152 can be spaced apart from the first light-emitting layer 142. For example, the second light-emitting layer 152 may be spaced apart from the first light-emitting layer 142 through bank insulation layer 116. Therefore, in the display device according to the embodiment of the present disclosure, it is possible to suppress light emission caused by a leakage current.

According to the embodiment of the present disclosure, in the display device 100, only one of the first light-emitting layer 142 and the second light-emitting layer 152 can create light in accordance with the user's selection or a predesignated condition.

The second lower electrode 151 in each of the subpixels RSP, GSP, and BSP can be spaced apart from the first lower electrode 141 in each of the corresponding subpixels RSP, GSP, and BSP. For example, a bank insulation layer 116 can be positioned between the first lower electrode 141 and the second lower electrode 151 in each of the subpixels RSP, GSP, and BSP. The bank insulation layer 116 can include an insulating material. For example, the bank insulation layer 116 can include an organic insulating material. The bank insulation layer 116 can include a material different from the material of the overcoating layer 115. However, the present disclosure is not limited thereto.

The second lower electrode 151 in each of the subpixels RSP, GSP, and BSP can be insulated from the first lower electrode 141 in each of the corresponding subpixels RSP, GSP, and BSP by the bank insulation layer 116. For example, the bank insulation layer 116 can cover an edge of the first lower electrode 141 and an edge of the second lower electrode 151 positioned in each of the subpixels RSP, GSP, and BSP.

The bank insulation layer 116 can separate a light-emitting area of the first light-emitting element 140 and a light-emitting area of the second light-emitting element 150. For example, the light-emitting area of the first light-emitting element 140 can be defined as an area of the first lower electrode 141 excluding an edge area of the first lower electrode 141 covered by the bank insulation layer 116. The light-emitting area of the second light-emitting element 150 can be defined as an area of the second lower electrode 151 an edge area of the second lower electrode 151 covered by the bank insulation layer 160. In this case, with reference to FIG. 4, a size of the light-emitting area of the first light-emitting element 140, which is defined in each of the subpixels RSP, GSP, and BSP, can be larger than a size of the light-emitting area of the second light-emitting element 150. However, the present disclosure is not limited thereto.

The first light-emitting layer 142 and the first upper electrode 143 of the first light-emitting element 140 positioned in each of the subpixels RSP, GSP, and BSP can be disposed on the first lower electrode 141 and the bank insulation layer 116. Specifically, the first light-emitting layer 142 and the first upper electrode 143 can be stacked on the bank insulation layer 116 and a partial area of the corresponding first lower electrode 141 exposed by the bank insulation layer 116. The second light-emitting layer 152 and the second upper electrode 153 of the second light-emitting element 150 positioned in each of the subpixels RSP, GSP, and BSP can be disposed on the second lower electrode 151 and the bank insulation layer 116. Specifically, the second light-emitting layer 152 and the second upper electrode 153 can be stacked on the bank insulation layer 116 and a partial area of the corresponding second lower electrode 151 exposed by the bank insulation layer 116.

The second upper electrode 153 in each of the subpixels RSP, GSP, and BSP can be electrically connected to the first upper electrode 143 of each of the corresponding subpixels RSP, GSP, and BSP. For example, a voltage, which is applied to the second upper electrode 153 of the second light-emitting element 150 positioned in each of the subpixels RSP, GSP, and BSP, can be equal to a voltage applied to the first upper electrode 143 of the first light-emitting element 140 positioned in each of the corresponding subpixels RSP, GSP, and BSP. The second upper electrode 153 in each of the subpixels RSP, GSP, and BSP can include the same material as the first upper electrode 143 in each of the corresponding subpixels RSP, GSP, and BSP. For example, the second upper electrode 153 in each of the subpixels RSP, GSP, and BSP can be formed simultaneously with the first upper electrode 143 in each of the corresponding subpixels RSP, GSP, and BSP. The second upper electrode 153 in each of the subpixels RSP, GSP, and BSP can extend to a top surface of the bank insulation layer 116 and be in direct contact with the first upper electrode 143 in each of the corresponding subpixels RSP, GSP, and BSP. The brightness of the first lens areas RWE, GWE, and BWE and the brightness of the second lens areas RNE, GNE, and BNE, which are positioned in the subpixels RSP, GSP, and BSP, can be controlled by a drive current generated in the corresponding subpixels RSP, GSP, and BSP.

The encapsulation member 180 can be positioned on the first and second light-emitting elements 140 and 150 in each of the subpixels RSP, GSP, and BSP. The encapsulation member 180 can suppress damage to the light-emitting elements 140 and 150 caused by moisture and impact from the outside. The encapsulation member 180 can have a multilayer structure. For example, the encapsulation member 180 can include a first encapsulation layer 181, a second encapsulation layer 182, and a third encapsulation layer 183 sequentially stacked. However, the embodiments of the present disclosure are not limited thereto.

The first encapsulation layer 181, the second encapsulation layer 182, and the third encapsulation layer 183 can include an insulating material. The second encapsulation layer 182 can include a material different from the material of the first encapsulation layer 181 and the third encapsulation layer 183. For example, the first encapsulation layer 181 and the third encapsulation layer 183 are inorganic encapsulation layers including an inorganic insulating material, and the second encapsulation layer 182 can include an organic encapsulation layer including an organic insulating material. Therefore, damage to the light-emitting elements 140 and 150 of the display device 100 caused by moisture and impact from the outside can be more effectively suppressed.

For example, the first encapsulation layer to the third encapsulation layer may be sequentially stacked on the upper electrode, the first encapsulation layer and the third encapsulation layer may be formed of an inorganic film layer including an inorganic material, and the second encapsulation layer may be formed of an organic film layer including an organic material.

The first encapsulation layer may be formed at the lowermost end of the encapsulation layer to be in contact with the upper surface of the upper electrode. The first encapsulation layer may be formed of a material such as silicon nitride SiNx, silicon oxide SiOx, silicon oxynitride SiON, or aluminum oxide Al2O3.

The second encapsulation layer may be formed on the first encapsulation layer. The second encapsulation layer may be formed of a material such as acrylic resin, epoxy resin, polyimide, polyethylene PE, or silicon oxycarbon SiOC.

The third encapsulation layer may be formed on the second encapsulation layer. The third encapsulation layer may be formed of the same material as the first encapsulation layer, but not limited thereto, the third encapsulation layer may be formed of different material from the first encapsulation layer.

Meanwhile, the encapsulation layers are not limited to three layers, for example, n layers alternately stacked between inorganic encapsulation layer and organic encapsulation layer (where n is an integer greater than 3) may be included.

A black matrix BM can be disposed on the encapsulation member 180. The black matrix BM can be disposed between the plurality of subpixels RSP, GSP, and BSP to reduce a mixture of colors of the plurality of subpixels RSP, GSP, and BSP. Therefore, the black matrix BM can be disposed to overlap the bank insulation layer 116.

The touch insulation layer 117 is disposed on the black matrix BM. The touch insulation layer 117 can be disposed between the encapsulation member 180, the black matrix BM, a touch electrode 190 and configured to insulate the touch electrode 190.

The touch insulation layer 117 can include an insulating material. For example, the touch insulation layer 117 can include an organic insulating material or an inorganic insulating material. However, the present disclosure is not limited thereto.

A plurality of touch electrodes 190 can be positioned on the touch insulation layer 117. In the display area, the plurality of touch electrodes 190 can be disposed above the first light-emitting element 140 and the second light-emitting element 150. The plurality of touch electrodes 190 can be disposed on the touch insulation layer 117 and spaced apart from one another. The plurality of touch electrodes 190 can be configured to sense a touch input applied from the outside by a user's finger, a touch pen, or the like.

With reference to FIGS. 5 and 6, the plurality of touch electrodes 190 is disposed to overlap the bank insulation layer 116 and the black matrix BM. Therefore, the plurality of touch electrodes 190 can be configured to minimize a restriction of a route of light generated by the first light-emitting element 140 and the second light-emitting element 150.

For example, the plurality of touch electrodes 190 can include a metallic material such as titanium (Ti), aluminum (Al), silver (Ag), copper (Cu), or a magnesium-silver alloy (Mg:Ag). However, the present disclosure is not limited thereto.

Meanwhile, a touch buffer layer can be further disposed between the encapsulation member 180 and the touch electrode 190. However, the present disclosure is not limited thereto. In addition, a touch bridge electrode can also be disposed on the encapsulation member 180 in addition to the touch electrode 190. However, the present disclosure is not limited thereto.

With reference to FIGS. 5 and 6, the first lens 161 and the plurality of second lenses 162 can be positioned on the encapsulation member 180 and the touch electrode 190 in each of the subpixels RSP, GSP, and BSP. The first lens 161 and the plurality of second lenses 162 can be disposed to cover edges of the plurality of touch electrodes 190. The first lens 161 can be disposed to correspond to the first light-emitting element 140, and the plurality of second lenses 162 can be disposed to correspond to the second light-emitting elements 150. For example, a width of the first lens 161 may be disposed to be greater than an interval between the two adjacent touch electrodes 190, and a width of each of the plurality of second lenses 162 may be disposed to be greater than an interval between the two adjacent touch electrodes 190. However, the present disclosure is not limited thereto.

The first lenses 161 can be positioned in the first lens areas RWE, GWE, and BWE in the subpixels RSP, GSP, and BSP.

For example, the light generated by the first light-emitting element 140 in each of the subpixels RSP, GSP, and BSP can be discharged through the first lenses 161 in the corresponding subpixels RSP, GSP, and BSP.

The first lens 161 can have a shape in which at least light in one direction may not be restricted. For example, a planar shape of the first lens 161 positioned in each of the subpixels RSP, GSP, and BSP can be a bar shape extending in a first direction.

In this case, the propagation direction of the light emitted from the first lens areas RWE, GWE, and BWE in the subpixels RSP, GSP, and BSP is not limited to the first direction. For example, the content (or images) provided through the first lens areas RWE, GWE, and BWE in the pixel PX can be shared with surrounding people adjacent to the user in the first direction. The case in which the content is provided through the first lens areas RWE, GWE, and BWE is a mode in which the content is provided within a first viewing angle range larger than a second viewing angle range in which the second lens areas RNE, GNE, and BNE are provided, and this mode can be referred to as a first mode.

The plurality of second lenses 162 can be positioned in the second lens areas RNE, GNE, and BNE in the subpixels RSP, GSP, and BSP.

For example, the light generated by the second light-emitting element 150 in each of the subpixels RSP, GSP, and BSP can be discharged through the plurality of second lenses 162 in the corresponding subpixels RSP, GSP, and BSP. In this case, the plurality of second lenses 162 can restrict the propagation direction, in which light passes through the second lenses 162, to the first direction and/or a second direction.

In an example, a planar shape of each of the plurality of second lenses 162 positioned in each of the subpixels RSP, GSP, and BSP can be a square shape. In this case, the propagation direction of the light emitted from the second lens areas RNE, GNE, and BNE of the subpixels RSP, GSP, and BSP can be limited to the first direction and the second direction. However, a planar shape of each of the plurality of second lenses 161 can be a circular shape. However, the present disclosure is not limited thereto.

In an example, the content provided by the second lens areas RNE, GNE, and BNE in the subpixels RSP, GSP, and BSP may not be shared with surrounding people adjacent to the user. The case in which the content is provided through the second lens areas RNE, GNE, and BNE is a mode in which the content is provided within the second viewing angle range smaller than the first viewing angle range in which the first lens areas RWE, GWE, and BWE are provided, and this mode can be referred to as a second mode.

Areas in the subpixels RSP, GSP, and BSP, in which the first lenses 161 are disposed, can be referred to as first light-emitting areas RE1, GE1, and BE1. For example, the first light-emitting areas RE1, GE1, and BE1 can be areas in which the light generated by the first light-emitting element 140 is discharged through the first lens 161.

Areas in the subpixels RSP, GSP, and BSP, in which the plurality of second lenses 162 is disposed, can be referred to as second light-emitting areas RE2, GE2, and BE2. For example, the second light-emitting areas RE2, GE2, and BE2 can be areas in which the light generated by the second light-emitting element 150 is discharged through the plurality of second lenses 162.

The first light-emitting areas RE1, GE1, and BE1 included in the first lens areas RWE, GWE, and BWE in the subpixels RSP, GSP, and BSP can have shapes corresponding to the plurality of first lenses 161 positioned in the first lens areas RWE, GWE, and BWE in the corresponding subpixels RSP, GSP, and BSP. For example, planar shapes of the first light-emitting areas RE1, GE1, and BE defined in the first lens areas RWE, GWE, and BWE in the subpixels RSP, GSP, and BSP can each be a bar shape extending in the first direction. However, the present disclosure is not limited thereto.

The first lens 161 positioned in each of the first lens areas RWE, GWE, and BWE in each of the subpixels RSP, GSP, and BSP can have the same size as each of the first light-emitting areas RE1, GE1, and BE included in the first lens areas RWE, GWE, and BWE in the corresponding subpixels RSP, GSP, and BSP. In addition, the first lens 161 can have a larger size than each of the first light-emitting areas RE1, GE1, and BE1. For example, a size of the first lens 161 may be equal or greater than a size of corresponding one of the first light-emitting areas RE1, GE1, and BE1. Therefore, it is possible to improve the efficiency of the light emitted from the first light-emitting areas RE1, GE1, and BE1 in the subpixels RSP, GSP, and BSP.

The second light-emitting areas RE2, GE2, and BE2 included in the plurality of second lenses areas RNE, GNE, and BNE in the subpixels RSP, GSP, and BSP can have shapes corresponding to the plurality of second lenses 162 positioned in the second lens areas RNE, GNE, and BNE in the corresponding subpixels RSP, GSP, and BSP. For example, planar shapes of the second light-emitting areas RE2, GE2, and BE2 included in the second lens areas RNE, GNE, and BNE in the subpixels RSP, GSP, and BSP can be polygonal or circular shapes. However, the present disclosure is not limited thereto.

Each of the plurality of second lenses 162 positioned in the second lens areas RNE, GNE, and BNE of the subpixels RSP, GSP, and BSP can have the same size as each of the second light-emitting areas RE2, GE2, and BE2 included in the second lens areas RNE, GNE, and BNE in the corresponding subpixels RSP, GSP, and BSP. In addition, the plurality of second lenses 162 can each have a larger size than each of the second light-emitting areas RE2, GE2, and BE2. For example, a size of each of the plurality of second lenses 162 may be equal or greater than a size of corresponding one of the second light-emitting areas RE2, GE2, and BE2. Therefore, it is possible to improve the efficiency of the light emitted from the second light-emitting areas RE2, GE2, and BE2 in the subpixels RSP, GSP, and BSP.

In the embodiment, the first lens area RWE, GWE, or BWE in one subpixel RSP, GSP, or BSP can include one first light-emitting area RE1, GE1, or BE1. The second lens area RNE, GNE, or BNE can include the plurality of second light-emitting areas RE2, GE2, or BE2 in one subpixel RSP, GSP, or BSP.

In the embodiment, one first lens 161 can be disposed in the first lens area RWE, GWE, or BWE in one subpixel RSP, GSP, or BSP. The plurality of second lenses 162 can be disposed in the second lens area RNE, GNE, or BNE in one subpixel RSP, GSP, or BSP.

In the embodiment, the sizes of the first light-emitting areas RE1, GE1, and BE1 can be different from one another for the respective subpixels RSP, GSP, and BSP. For example, the first light-emitting area BE1 in the blue subpixel BSP can have a different size from the second light-emitting area GE1 in the green subpixel GSP and have a different size from the first light-emitting area RE1 in the red subpixel RSP. The size of the first light-emitting area BE1 in the blue subpixel BSP can be larger than the size of the first light-emitting area GE1 in the green subpixel GSP. The size of the first light-emitting area GE1 in the green subpixel GSP can be larger than the size of the first light-emitting area RE1 in the red subpixel RSP. Therefore, in the display device according to the embodiment of the present disclosure, the efficiency deviation between the first light-emitting elements 140 positioned in the first lens areas RWE, GWE, and BWE in the subpixels RSP, GSP, and BSP can be compensated by the sizes of the first light-emitting areas RE1, GE1, and BE1 defined in the first lens areas RWE, GWE, and BWE in the subpixels RSP, GSP, and BSP. However, the present disclosure is not limited thereto. The areas of the second light-emitting areas RE2, GE2, and BE2 positioned in the second lens areas RNE, GNE, and BNE may also be implemented to be not equal to one another.

In the embodiment, areas of the second light-emitting areas RE2, GE2, and BE2 positioned in the second lens areas RNE, GNE, and BNE in the plurality of subpixels RSP, GSP, and BSP can be designated as particular values. For example, the areas of the second light-emitting areas RE2, GE2, and BE2 positioned in the second lens areas RNE, GNE, and BNE can be implemented to be equal to one another. The area of each of the second light-emitting areas RE2, GE2, and BE2 positioned in the second lens areas RNE, GNE, and BNE in the plurality of subpixels RSP, GSP, and BSP can be equal to the area of each of the second light-emitting areas RE2, GE2, and BE2 included in the second lens areas RNE, GNE, and BNE in the adjacent subpixels RSP, GSP, and BSP.

In the embodiment, the number of second light-emitting areas RE2, GE2, and BE2 can vary depending on the subpixels RSP, GSP, and BSP. For example, the number of second light-emitting areas BE2 defined in the second lens area BNE in the blue subpixel BSP and the number of second light-emitting areas GE2 defined in the second lens area GNE in the green subpixel GSP can be larger than the number of second light-emitting areas RE2 defined in the second lens area RNE in the red subpixel RSP. In this case, the efficiency deviation between the second light-emitting elements 150 positioned in the second lens areas RNE, GNE, and BNE in the subpixels RSP, GSP, and BSP can be compensated by the number of second light-emitting areas RE2, GE2, and BE2 defined in the second lens areas RNE, GNE, and BNE in the subpixels RSP, GSP, and BSP.

In the embodiment, the lens protective layer 170 can be positioned on the first lens 161 and the plurality of second lenses 162 in the subpixels RSP, GSP, and BSP. The lens protective layer 170 can include an insulating material. For example, the lens protective layer 170 can include an organic insulating material. A refractive index of the lens protective layer 170 can be smaller than a refractive index of the first lens 161 and a refractive index of the second lens 162 positioned in each of the subpixels RSP, GSP, and BSP. Therefore, in the display device 100 according to the embodiment of the present disclosure, the light, which has passed through the first lens 161 and the second lens 162 in each of the subpixels RSP, GSP, and BSP, may not be reflected toward the substrate 110 because of a difference from the refractive index of the lens protective layer 170.

In the display device, all the first lens and the plurality of second lenses can be disposed above the light-emitting element, the black matrix, and the touch electrode in one subpixel in order to selectively provide different viewing angle modes to the user. In this case, a part of the light emitted from the light-emitting element, on which the plurality of second lenses is disposed, can be reflected by the black matrix in the area between the plurality of second lenses at the upper side of the light-emitting element. The black matrix is made of a material that absorbs light, but the black matrix cannot absorb 100% of the amount of light entering the black matrix. Therefore, a part of the light entering the black matrix can be reflected by a bottom surface of the black matrix. Further, the light reflected by the black matrix can be reflected by the lower electrode, and the light can leak through another second lens adjacent to and different from the second lens disposed above a point at which the light is emitted. In addition, the light is discharged at a relatively high angle because of the leak of light described above, which can distort a viewing angle range set to be provided by the plurality of second lenses. For this reason, the functions of the plurality of second lenses set to restrictively provide the viewing angle range to the user can deteriorate. In addition, the deterioration in functions of the plurality of second lenses can cause a problem in that the content (or image) is shared even in a mode in which the content is not shared with surrounding people adjacent to the user. For example, in case that the person, who need not share the content, is the driver of the vehicle, a severe safety problem can occur.

In the display device 100 according to the embodiment of the present disclosure, the opening portion OP1 is disposed in the reflective layer 151a of the second lower electrode 151 in an area corresponding to an area between the plurality of second lenses 162, which can minimize a degree to which the light emitted from the second light-emitting element 150 is reflected by the second lower electrode 151 in the area between the plurality of second lenses 162.

Specifically, the opening portion OP1 is disposed in the reflective layer 151a of the second lower electrode 151 and overlaps the area between the plurality of second lenses 162. In this case, a part of the light emitted from the second light-emitting element 150 can be reflected toward the second lower electrode 151 of the second light-emitting element 150 by the black matrix BM in the area between the plurality of second lenses 162 at the upper side of the second light-emitting element 150. However, as illustrated in FIG. 6, the light L reflected by the black matrix BM can reach the opening portion OP1 of the reflective layer 151a. Therefore, the light L reflected toward the second lower electrode 151 from the black matrix BM may not be reflected by the reflective layer 151a, which can minimize light L′ reflected toward another adjacent second lens 162. In addition, the second lower electrode 151 can minimize the reflection of the light, which is emitted from the second light-emitting element 150, and the reflection of external light, which can provide the low-reflection display device 100.

In the display device 100 according to the embodiment of the present disclosure, the light L′, which is emitted from the second light-emitting element 150 and reflected by the second lower electrode 151 in the area between the plurality of second lenses 162, is minimized, which can suppress the distortion of the viewing angle range set to be provided by the plurality of second lenses 162.

Specifically, in the display device 100 according to the embodiment of the present disclosure, the opening portion OP1 is disposed in the reflective layer 151a of the second lower electrode 151 and overlaps the area between the plurality of second lenses 162, which can minimize a degree to which the light emitted from the second light-emitting element 150 is reflected by the second lower electrode 151 in the area between the plurality of second lenses 162. Therefore, it is possible to minimize a high-angle leak of light caused when the light emitted from the second light-emitting element 150 is discharged at a relatively high angle through another second lens 162 adjacent to or different from the second lens 162 disposed above the point at which the light is emitted. Therefore, the distortion of the viewing angle range set to be provided by the plurality of second lenses 162 can be suppressed, and the reliability related to the function of the display device 100, which selectively provides different viewing angle modes, can be improved. Therefore, it is possible to minimize a severe safety problem that occurs when the content, when need not be shared with the driver of the vehicle, is shared with the driver of the vehicle.

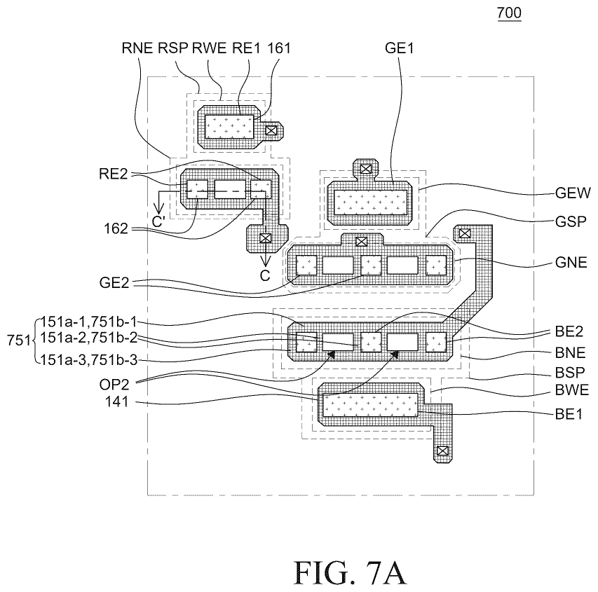

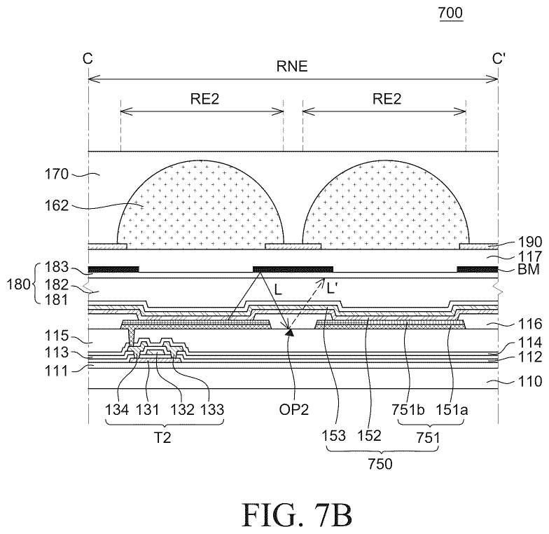

FIG. 7A is an enlarged top plan view of a display device according to another embodiment of the present disclosure. FIG. 7B is a cross-sectional view taken along line C-C′ in FIG. 7A. A display device 700 in FIGS. 7A and 7B is substantially identical in configuration to the display device 100 in FIGS. 1 to 6, except that an opening portion OP2 is also disposed in a transparent conductive layer 751b of a second lower electrode 751. Therefore, repeated descriptions of the identical components will be omitted or may be briefly provided.

With reference to FIGS. 7A and 7B, the opening portion OP2 is disposed in the reflective layer 151a and the transparent conductive layer 751b of the second lower electrode 751 and overlaps the area between the plurality of second lenses 162. In this case, the transparent conductive layer 751b is disposed in an area that overlaps the reflective layer 151a.

With reference to FIG. 7A, the reflective layer 151a of the second lower electrode 751 includes the first part 151a-1, the plurality of second parts 151a-2, and the third part 151a-3, and the transparent conductive layer 751b of the second lower electrode 751 includes a first part 751b-1, a plurality of second parts 751b-2, and a third part 751b-3. Further, the opening portion OP2 has a hole shape surrounded by the first parts 151a-1 and 751b-1, the plurality of second parts 151a-2 and 751b-2, and the third parts 151a-3 and 751b-3 of the reflective layer 151a and the transparent conductive layer 751b.

The first parts 151a-1 and 751b-1 of the reflective layer 151a and the transparent conductive layer 751b of the second lower electrode 751 can include a part of the reflective layer 151a, a part of the transparent conductive layer 751b, and portions extending outward from a part of the reflective layer 151a and a part of the transparent conductive layer 751b so as to be connected to the second transistor T2. Therefore, the first parts 151a-1 and 751b-1 can be connected to the second transistor T2. For example, the first parts 151a-1 and 751b-1 can be connected to the second transistor T2 through a contact hole formed in the overcoating layer 115 in an area corresponding to the portions extending outward from a part of the reflective layer 151a and a part of the transparent conductive layer 751b. However, the present disclosure is not limited thereto.

The plurality of second parts 151a-2 and 751b-2 of the reflective layer 151a and the transparent conductive layer 751b of the second lower electrode 151 extend from the first parts 151a-1 and 751b-1 and are disposed to overlap the plurality of second lenses 162. The plurality of second parts 151a-2 and 751b-2 can be parts corresponding to areas of the reflective layer 151a and the transparent conductive layer 751b of the second lower electrode 751 in which the plurality of second lenses 162 is disposed.

The third parts 151a-3 and 751b-3 of the reflective layer 151a and the transparent conductive layer 751b of the second lower electrode 751 are parts of the reflective layer 151a and the transparent conductive layer 751b that are disposed opposite to the first parts 151a-1 and 751b-1 based on the plurality of second parts 151a-2 and 751b-2. The third parts 151a-3 and 751b-3 can be disposed opposite to the first parts 151a-1 and 751b-1 and connect the plurality of second parts 151a-2 and 751b-2.

With reference to FIG. 7B, the transparent conductive layer 751b is disposed in an area that overlaps the reflective layer 151a. Therefore, the bank insulation layer 116 can be disposed in the opening portion OP2. For example, the bank insulation layer 116 can be disposed on the overcoating layer 115 through the opening portion OP2 of the second lower electrode 751.

In the display device 700 according to another embodiment of the present disclosure, the opening portion OP2 is disposed in the reflective layer 151a and the transparent conductive layer 751b of the second lower electrode 751 in the area corresponding to the area between the plurality of second lenses 162, which can minimize a degree to which the light emitted from the second light-emitting element 750 is reflected by the second lower electrode 751 in the area between the plurality of second lenses 162.

Specifically, the opening portion OP2 is disposed in the reflective layer 151a and the transparent conductive layer 751b of the second lower electrode 751 and overlaps the area between the plurality of second lenses 162. For example, even in the case of the transparent conductive layer 751b made of a transparent conductive material, the transparent conductive layer 751b cannot transmit the entire light entering the transparent conductive layer 751b, and the transparent conductive layer 751b reflects a part of the light. Therefore, in the display device 700 according to another embodiment of the present disclosure, the opening portion OP2 is disposed not only in the reflective layer 151a but also in the transparent conductive layer 751b. In this case, a part of the light emitted from the second light-emitting element 750 can be reflected toward the second lower electrode 751 of the second light-emitting element 750 by the black matrix BM in the area between the plurality of second lenses 162 at the upper side of the second light-emitting element 750. However, as illustrated in FIG. 7B, the light L reflected by the black matrix BM can reach the opening portion OP2 of the reflective layer 151a and the transparent conductive layer 751b. Therefore, the light L reflected toward the second lower electrode 751 from the black matrix BM may not be reflected by the reflective layer 151a and the transparent conductive layer 751b, which can further minimize light L′ reflected toward another adjacent second lens 162. In addition, the second lower electrode 751 can minimize the reflection of the light, which is emitted from the second light-emitting element 750, and the reflection of external light, which can provide the low-reflection display device 700.

In the display device 700 according to another embodiment of the present disclosure, the light L′, which is emitted from the second light-emitting element 750 and reflected by the second lower electrode 751 in the area between the plurality of second lenses 162, is minimized, which can suppress the distortion of the viewing angle range set to be provided by the plurality of second lenses 162.

Specifically, in the display device 700 according to another embodiment of the present disclosure, the opening portion OP2 is disposed in the reflective layer 151a and the transparent conductive layer 751b of the second lower electrode 751 and overlaps the area between the plurality of second lenses 162, which can minimize a degree to which the light emitted from the second light-emitting element 750 is reflected by the second lower electrode 751 in the area between the plurality of second lenses 162. As such, it is possible to further minimize a high-angle leak of light caused when the light emitted from the second light-emitting element 750 is discharged at a relatively high angle through another second lens 162 adjacent to or different from the second lens 162 disposed above the point at which the light is emitted. Further, the distortion of the viewing angle range set to be provided by the plurality of second lenses 162 can be suppressed, and the reliability related to the function of the display device 700, which selectively provides different viewing angle modes, can be further improved. Therefore, it is possible to further minimize a severe safety problem that occurs when the content, when need not be shared with the driver of the vehicle, is shared with the driver of the vehicle.

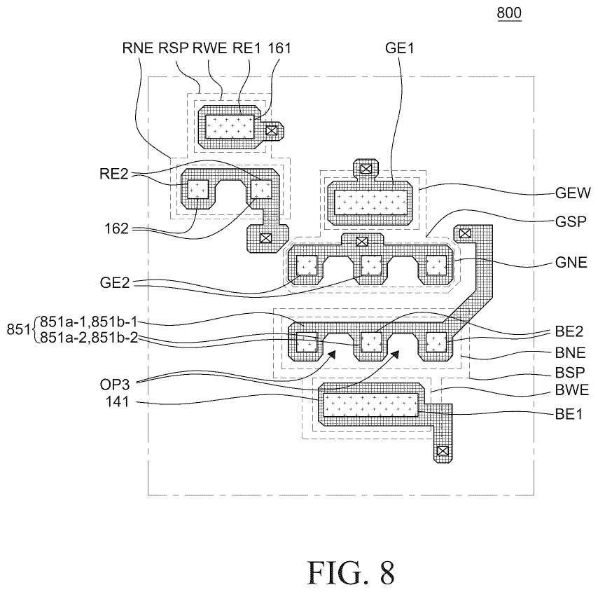

FIG. 8 is an enlarged top plan view of a display device according to still another embodiment of the present disclosure. A display device 800 in FIG. 8 is substantially identical in configuration to the display device 700 in FIGS. 7A and 7B, except for a planar shape of an opening portion OP3. Therefore, a repeated description will be omitted or may be briefly provided.

With reference to FIG. 8, the opening portion OP3 is disposed in a reflective layer 851a and a transparent conductive layer 851b of a second lower electrode 851 and overlaps the area between the plurality of second lenses 162. In this case, the transparent conductive layer 851b is disposed in an area that overlaps the reflective layer 851a.

The reflective layer 851a of the second lower electrode 851 includes a first part 851a-1 and a plurality of second parts 851a-2, and the transparent conductive layer 851b of the second lower electrode 851 includes a first part 851b-1 and a plurality of second parts 851b-2. Further, a planar shape of the opening portion OP3 can be a groove shape opened at a side opposite to the first parts 851a-1 and 851b-1.

The first parts 851a-1 and 851b-1 of the reflective layer 851a and the transparent conductive layer 851b of the second lower electrode 851 can include a part of the reflective layer 851a, a part of the transparent conductive layer 851b, and portions extending outward from a part of the reflective layer 851a and a part of the transparent conductive layer 851b so as to be connected to the second transistor T2. Therefore, the first parts 851a-1 and 851b-1 can be connected to the second transistor T2. For example, the first parts 851a-1 and 851b-1 can be connected to the second transistor T2 through contact hole formed in the overcoating layer 115 in an area corresponding to the portions extending outward from a part of the reflective layer 851a and a part of the transparent conductive layer 851b. However, the present disclosure is not limited thereto.

The plurality of second parts 851a-2 and 851b-2 of the reflective layer 851a and the transparent conductive layer 851b of the second lower electrode 851 extend from the first parts 851a-1 and 851b-1 and are disposed to overlap the plurality of second lenses 162. The plurality of second parts 851a-2 and 851b-2 can be parts corresponding to areas of the reflective layer 851a and the transparent conductive layer 851b of the second lower electrode 851 in which the plurality of second lenses 162 is disposed.

In the display device 800 according to another embodiment of the present disclosure, the opening portion OP3 is disposed in the reflective layer 851a and the transparent conductive layer 851b of the second lower electrode 851 in the area corresponding to the area between the plurality of second lenses 162, which can minimize a degree to which the light emitted from the second light-emitting element 850 is reflected by the second lower electrode 851 in the area between the plurality of second lenses 162.

Specifically, the opening portion OP3 is disposed in the reflective layer 851a and the transparent conductive layer 851b of the second lower electrode 851 and overlaps the area between the plurality of second lenses 162. In this case, a part of the light emitted from the second light-emitting element 850 can be reflected toward the second lower electrode 851 of the second light-emitting element 850 by the black matrix BM in the area between the plurality of second lenses 162 at the upper side of the second light-emitting element 850. However, as illustrated in FIG. 8, the light L reflected by the black matrix BM can reach the opening portion OP3 of the reflective layer 851a and the transparent conductive layer 851b. Therefore, the light L reflected toward the second lower electrode 851 from the black matrix BM may not be reflected by the reflective layer 851a and the transparent conductive layer 851b, which can further minimize light L′ reflected toward another adjacent second lens 162. In addition, the second lower electrode 851 can minimize the reflection of the light, which is emitted from the second light-emitting element 850, and the reflection of external light, which can provide the low-reflection display device 800.

In the display device 800 according to another embodiment of the present disclosure, the light L′, which is emitted from the second light-emitting element 850 and reflected by the second lower electrode 851 in the area between the plurality of second lenses 162, is minimized, which can suppress the distortion of the viewing angle range set to be provided by the plurality of second lenses 162.

Specifically, in the display device 800 according to another embodiment of the present disclosure, the opening portion OP3 is disposed in the reflective layer 851a and the transparent conductive layer 851b of the second lower electrode 851 and overlaps the area between the plurality of second lenses 162, which can minimize a degree to which the light emitted from the second light-emitting element 850 is reflected by the second lower electrode 851 in the area between the plurality of second lenses 162. As such, it is possible to further minimize a high-angle leak of light caused when the light emitted from the second light-emitting element 850 is discharged at a relatively high angle through another second lens 162 adjacent to or different from the second lens 162 disposed above the point at which the light is emitted. Therefore, the distortion of the viewing angle range set to be provided by the plurality of second lenses 162 can be suppressed, and the reliability related to the function of the display device 800, which selectively provides different viewing angle modes, can be further improved. Accordingly, it is possible to further minimize a severe safety problem that occurs when the content, when need not be shared with the driver of the vehicle, is shared with the driver of the vehicle.

The example embodiments of the present disclosure can also be described as follows:

According to an aspect of the present disclosure, a display device including: a substrate on which a plurality of pixels each including a plurality of subpixels configured to display different colors is disposed; a first light-emitting element and a second light-emitting element disposed in each of the plurality of subpixels; a first lens disposed to overlap a light-emitting area of the first light-emitting element and configured to provide a viewing angle of a first value; and a plurality of second lenses disposed to overlap light-emitting areas of the second light-emitting elements and configured to provide a viewing angle of a second value lower than the viewing angle of the first value, in which the first light-emitting element and the second light-emitting element each include: an anode including a reflective layer, and in which an opening portion is disposed in the reflective layer and overlaps an area between the plurality of second lenses.

The first light-emitting element and the second light-emitting element may each further include a light-emitting layer disposed on the anode; and a cathode disposed on the light-emitting layer, and the anode further includes a transparent conductive layer disposed on the reflective layer.

Among the plurality of subpixels, a number of light-emitting areas of the second light-emitting element defined by the plurality of second lenses in a first subpixel may be different from a number of light-emitting areas of the second light-emitting element defined by the plurality of second lenses in a second subpixel.

The display device may further comprise a lens protective layer disposed on the first lens and the plurality of second lenses, wherein a refractive index of the lens protective layer is smaller than each of a refractive index of the first lens and a refractive index of the second lens.

The display device can further comprise a bank insulation layer configured to cover edges of the anodes of the first light-emitting element and the second light-emitting element.

The bank insulation layer can overlap the opening portion.

The display device can further comprise an encapsulation member disposed on the first light-emitting element and the second light-emitting element; and a black matrix disposed on the encapsulation member.

The black matrix can be disposed to overlap the bank insulation layer.

The display device can further comprise a plurality of touch electrodes disposed above the black matrix and configured to overlap the bank insulation layer and the black matrix.

The first lens and the plurality of second lenses can be disposed to cover edges of the touch electrodes.

The display device can further comprise a transistor disposed on the substrate.

The reflective layer can comprise a first part electrically connected to the transistor; and a plurality of second parts extending from the first part and disposed to overlap the plurality of second lenses.

A planar shape of the opening portion can be a groove shape opened at a side opposite to the first part.

The reflective layer can further comprise a third part disposed at a side opposite to the first part and configured to connect the plurality of second parts.

A planar shape of the opening portion can be a hole shape surrounded by the first part, the plurality of second parts, and the third part.

The transparent conductive layer can be further disposed in the opening portion.

The transparent conductive layer can be disposed in an area that overlaps the reflective layer.

According to another aspect of the present disclosure, a display device including: a substrate including a display area in which a plurality of subpixels is disposed, and a non-display area disposed along a periphery of the display area; a first light-emitting element and a second light-emitting element disposed in each of the plurality of subpixels and each comprising an anode, a light-emitting layer disposed on the anode, and a cathode disposed on the light-emitting layer, and the anode comprises a reflective layer; a first lens disposed to overlap a light-emitting area of the first light-emitting element and configured to provide a viewing angle of a first value; and a plurality of second lenses disposed to overlap light-emitting areas of the second light-emitting elements and configured to provide a viewing angle of a second value lower than the viewing angle of the first value, in which the reflective layer of the second light-emitting element has an opening portion disposed in an area that overlaps an area between the plurality of second lenses.

The anode may further comprise a transparent conductive layer disposed on the reflective layer.

Among the plurality of subpixels, a number of light-emitting areas of the second light-emitting element defined by the plurality of second lenses in a first subpixel may be different from a number of light-emitting areas of the second light-emitting element defined by the plurality of second lenses in a second subpixel.

The display device may further comprise a lens protective layer disposed on the first lens and the plurality of second lenses, wherein a refractive index of the lens protective layer is smaller than each of a refractive index of the first lens and a refractive index of the second lens.

The display device can comprise a plurality of transistors disposed on the substrate and respectively connected to the first light-emitting element and the second light-emitting element.

The reflective layer can comprise a first part electrically connected to the transistor; and a plurality of second parts extending from the first part and disposed to overlap the plurality of second lenses.

A planar shape of the opening portion can be a groove shape opened at a side opposite to the first part.

The reflective layer can further comprise a third part disposed at a side opposite to the first part and configured to connect the plurality of second parts.

A planar shape of the opening portion can be a hole shape surrounded by the first part, the plurality of second parts, and the third part.

The display device can further comprise an overcoating layer disposed between the plurality of transistors and the first light-emitting element and the second light-emitting element.

The transparent conductive layer can be disposed on the overcoating layer through the opening portion.

The transparent conductive layer can be disposed in an area that overlaps the reflective layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a plurality of pixels on a substrate, each of the plurality of pixels including a plurality of subpixels configured to display different colors, the plurality of subpixels including a first light-emitting element and a plurality of second light-emitting elements;
a first lens overlapping a light-emitting area of the first light-emitting element, and configured to provide a viewing angle of a first value; and
a plurality of second lenses overlapping light-emitting areas of the plurality of second light-emitting elements, and configured to provide a viewing angle of a second value smaller than the first value,
wherein the first light-emitting element and the plurality of second light-emitting elements each comprise an anode including a reflective layer,
wherein an opening portion is disposed in the reflective layer and overlaps an area between the plurality of second lenses.

2. The display device of claim 1, wherein the first light-emitting element and the plurality of second light-emitting elements each further comprises:
a light-emitting layer on the anode; and
a cathode on the light-emitting layer, and
wherein the anode further comprises a transparent conductive layer on the reflective layer.

3. The display device of claim 1, wherein among the plurality of subpixels, a number of light-emitting areas of the second light-emitting element defined by the plurality of second lenses in a first subpixel is different from a number of light-emitting areas of the second light-emitting element defined by the plurality of second lenses in a second subpixel.

4. The display device of claim 1, further comprising a lens protective layer disposed on the first lens and the plurality of second lenses,
wherein a refractive index of the lens protective layer is smaller than each of a refractive index of the first lens and a refractive index of the second lens.

5. The display device of claim 1, further comprising:
a bank insulation layer configured to cover edges of the anodes of the first light-emitting element and the plurality of second light-emitting elements,
wherein the bank insulation layer overlaps the opening portion.

6. The display device of claim 2, further comprising:
an encapsulation member on the first light-emitting element and the plurality of second light-emitting elements; and
a black matrix on the encapsulation member,
wherein the black matrix is disposed to overlap the bank insulation layer.

7. The display device of claim 3, further comprising:
a plurality of touch electrodes on the black matrix, and configured to overlap the bank insulation layer and the black matrix,
wherein the first lens and the plurality of second lenses are disposed to cover edges of the plurality of touch electrodes.

8. The display device of claim 1, further comprising:
a transistor on the substrate,
wherein the reflective layer comprises:
a first part electrically connected to the transistor; and
a plurality of second parts extending from the first part and disposed to overlap the plurality of second lenses.

9. The display device of claim 5, wherein a planar shape of the opening portion is a groove shape opened at a side opposite to the first part.

10. The display device of claim 5, wherein the reflective layer further comprises a third part disposed at a side opposite to the first part and configured to connect the plurality of second parts.

11. The display device of claim 7, wherein a planar shape of the opening portion is a hole shape surrounded by the first part, the plurality of second parts, and the third part.

12. The display device of claim 2, wherein the transparent conductive layer is further disposed in the opening portion.

13. The display device of claim 2, wherein the transparent conductive layer is disposed in an area that overlaps the reflective layer.

14. A display device comprising:
a substrate comprising a display area including a plurality of subpixels, and a non-display area adjacent to the display area;
a first light-emitting element and a second light-emitting element in each of the plurality of subpixels, and each of the first light-emitting element and the second light-emitting element comprising an anode, a light-emitting layer on the anode, and a cathode on the light-emitting layer,
wherein the anode comprises a reflective layer;
a first lens disposed to overlap a light-emitting area of the first light-emitting element and configured to provide a viewing angle of a first value; and
a plurality of second lenses disposed to overlap light-emitting areas of the second light-emitting elements and configured to provide a viewing angle of a second value lower than the viewing angle of the first value,
wherein the reflective layer of the second light-emitting element has an opening portion disposed in an area that overlaps an area between the plurality of second lenses.

15. The display device of claim 14, wherein the anode further comprises a transparent conductive layer on the reflective layer.

16. The display device of claim 14, wherein among the plurality of subpixels, a number of light-emitting areas of the second light-emitting element defined by the plurality of second lenses in a first subpixel is different from a number of light-emitting areas of the second light-emitting element defined by the plurality of second lenses in a second subpixel.

17. The display device of claim 14, further comprising a lens protective layer disposed on the first lens and the plurality of second lenses,
wherein a refractive index of the lens protective layer is smaller than each of a refractive index of the first lens and a refractive index of the second lens.

18. The display device of claim 15, further comprising:
a plurality of transistors on the substrate respectively connected to the first light-emitting element and the second light-emitting element,
wherein the reflective layer comprises:
a first part electrically connected to the transistor; and
a plurality of second parts extending from the first part and disposed to overlap the plurality of second lenses.

19. The display device of claim 18, wherein a planar shape of the opening portion is a groove shape opened at a side opposite to the first part.

20. The display device of claim 18, wherein the reflective layer further comprises a third part disposed at a side opposite to the first part and configured to connect the plurality of second parts.

21. The display device of claim 20, wherein a planar shape of the opening portion is a hole shape surrounded by the first part, the plurality of second parts, and the third part.

22. The display device of claim 18, further comprising:
an overcoating layer disposed between the plurality of transistors and the first light-emitting element and the second light-emitting element,
wherein the transparent conductive layer is disposed on the overcoating layer through the opening portion.

23. The display device of claim 15, wherein the transparent conductive layer is disposed in an area that overlaps the reflective layer.
